(19) United States
(12) Patent Application Publication
(10) Pub. No.: US 2019/0064563 A1
(43) Pub. Date: Feb. 28, 2019

(54) ARRAY SUBSTRATE, METHOD OF MANUFACTURING THE SAME, AND DISPLAY PANEL

(71) Applicants: HKC CORPORATION LIMITED, Shenzhen, Goungdong (CN); CHONGQING HKC OPTOELECTRONICS TECHNOLOGY CO., LTD., Jieshi, Chongqing (CN)

(72) Inventor: Yu-jen CHEN, Jieshi (CN)

(73) Assignees: HKC Corporation Limited, Shenzhen, Goungdong (CN); Chongqing HKC Optoelectronics Technology Co., Ltd., Jieshi, Chongqing (CN)

(21) Appl. No.: 15/744,115

(22) PCT Filed: Jul. 26, 2017
(86) PCT No.: PCT/CN2017/094548

§ 371 Date: Nov. 1, 2018

(30) Foreign Application Priority Data
Apr. 24, 2017 (CN) 201710270695.9

(51) Int. Cl. G02F 1/1362; G02F 1/1343; H01L 27/12; G02F 1/1368

(52) U.S. Cl. CPC G02F 1/1362; G02F 1/13439; H01L 27/1248; H01L 27/1262; G02F 1/1368; G02F 1/134363; G02F 1/136286; G02F 2001/136222; G02F 2201/123; G02F 2001/136231; G02F 2001/136295; G02F 1/136227

(57) ABSTRACT

Provided are an active switch array substrate, a method of manufacturing the same, and a display panel. The method of manufacturing includes: forming gate electrodes of active switches, an insulating layer, an active layer and an ohmic contact layer on a substrate; forming source electrodes and drain electrodes of the active switches on the ohmic contact layer and the insulating layer; forming a protective layer on the source electrodes, the drain electrodes and the insulating layer; forming a color filter layer on the protective layer, and exposing and developing the color filter layer; forming a photoresist layer, which is penetrable by visible light, on the color filter layer and the protective layer; and forming a transparent conducting layer directly on the photoresist layer, and etching the transparent conducting layer to form a pixel electrode layer.

### TECHNICAL FIELD

The present disclosure belongs to the technical field of display screens, and for example, relates to an array substrate, a method of manufacturing the same, and a display panel.

### BACKGROUND

An increasing number of display panel manufacturers use a technology of forming a color filter on array (COA) of thin-film transistors (TFTs) and a white, red, green and blue (WRGB) technology. The COA technology can improve the quality of image on a curved surface of a display panel or simplify a structure of an upper plate, e.g., simplify a structure of an over coat (OC) of the upper plate of an In-Plane Switching (IPS) liquid crystal mode. The WRGB technology can increase a penetration rate of the display panel, reduce the energy consumption of the display panel, and save backlight cost.

In the related art, a technology of manufacturing an array of the display panel having a COA structure and using the WRGB technology is as follows: according to the COA structure in combination with the WRGB technology, after the manufacture of gate electrodes and source electrodes, a procedure of forming a first insulating layer is firstly carried out; and then, steps of coating, exposing and developing a color filter layer (including a red filter, a green filter and a blue filter) are completed, and steps of coating, exposing and developing a transparent photoresist layer are completed. A procedure of forming a second insulating layer is conducted after structures of the color filter layer and the transparent photoresist layer are formed. Then a photoresist layer is coated, exposed using a mask with through holes, and developed and etched to remove parts of the first insulating layer and the second insulating layer corresponding to the through holes and located above the array. Subsequently, the photoresist layer is removed to continue a next process of manufacturing pixel electrodes (PEs).

In the industry of display panel industry (LCD), the production cost of TFT LCD remains large due to the complex processes and large device investment. With fierce market competition, reduction of the production cost of the display panel has become a development direction of the display panel industry. A production line of the display panel of thin-film transistors in the related art is suitable for a production technology of three primary colors (red, green and blue), and a production device and a workshop space related to the transparent photoresist are not provided. Therefore, there is a need to develop a new technology of producing a display panel, so as to reduce the production cost and increase the production efficiency.

### SUMMARY

The present disclosure provides an array substrate, a method of manufacturing the same, and a display panel, so as to reduce production cost of the display panel and increase production efficiency.

The method of manufacturing the array substrate provided in the present disclosure includes following steps:

forming gate electrodes of active switches, an insulating layer, an active layer and an ohmic contact layer on a substrate;

forming source electrodes and drain electrodes of the active switches on the ohmic contact layer and the insulating layer;

forming a protective layer on the source electrodes, the drain electrodes and the insulating layer;

forming a color filter layer on the protective layer, and exposing and developing the color filter layer;

forming a photoresist layer, which is penetrable by visible light, on the color filter layer and the protective layer; and

forming a transparent conducting layer directly on the photoresist layer, and etching the transparent conducting layer to form a pixel electrode layer.

The present disclosure further provides a method of manufacturing an active switch array substrate, including following steps:

forming gate electrodes of an active switches, an insulating layer, an active layer and an ohmic contact layer on a substrate;

forming source electrodes and drain electrodes of the active switches on the ohmic contact layer and the insulating layer;

forming a protective layer on the source electrodes, the drain electrodes, the active layer and an exposed surface of the insulating layer;

treating the protective layer to expose part of surfaces of the drain electrodes or the source electrodes;

forming a color filter layer on the protective layer, and exposing and developing the color filter layer;

forming a photoresist layer, which is penetrable by visible light, on the color filter layer and the protective layer; and

forming a transparent conducting layer directly on the photoresist layer and etching the transparent conducting layer to form a pixel electrode layer.

The present disclosure further provides an active switch array substrate, including:

a substrate;

gate electrodes of active switches located on the substrate;

an insulating layer located on the substrate and the gate electrodes;

an active layer located on the insulating layer and configured to be channels of the active switches;

an ohmic contact layer located on the active layer;

source electrodes and drain electrodes of the active switches, located on the ohmic contact layer and the insulating layer;

a protective layer located on the source electrodes, the drain electrodes and the insulating layer;

a color filter layer located on the protective layer and including filter units;

a photoresist layer located on the color filter layer and the protective layer and formed by forming photoresist, which is penetrable by visible light; and

a pixel electrode layer directly formed on the photoresist layer.

The present disclosure further provides a display panel, including:

a backlight module configured to provide an illumination source;

a first substrate, including: a substrate; gate electrodes of active switches, located on one side of the substrate; an insulating layer located on the substrate and the gate electrodes; an active layer located on the insulating layer; an ohmic contact layer located on the active layer; source electrodes and drain electrodes of the active switches, located on the ohmic contact layer and the insulating layer; a protective layer located on the source electrodes, the drain electrodes and the insulating layer; a color filter layer located on the protective layer; a photoresist layer located on the color filter layer and the protective layer and formed by forming photoresist which is penetrable by visible light; a pixel electrode layer directly located on the photoresist layer; a first alignment film located on the photoresist layer; and a first polarizer arranged on the other side of the first glass substrate;

a second substrate buckled with the first substrate; and

a liquid crystal layer filling between the first substrate and the second substrate.

### BRIEF DESCRIPTION OF DRAWINGS

FIG. 1 is a schematic diagram illustrating steps of technological process of an active switch array substrate provided in the present embodiment;

FIG. 2 is a flow chart illustrating the manufacture of an active switch array substrate provided in the present embodiment;

FIG. 3 is a schematic diagram illustrating a structure of an active switch array substrate provided in the present embodiment; and

FIG. 4 is a schematic diagram illustrating a structure of a display panel provided in the present embodiment.

### DETAILED DESCRIPTION

The following embodiments and features in the embodiments may be combined in case of no conflict. It should be understood that embodiments described herein are only used for explaining, instead of limiting, the present disclosure.

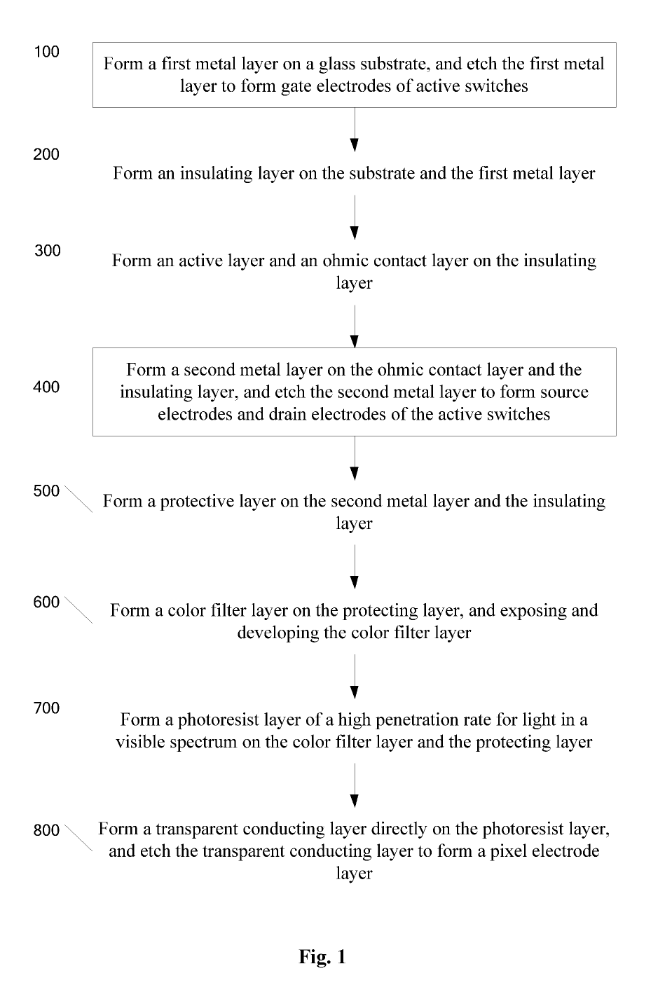

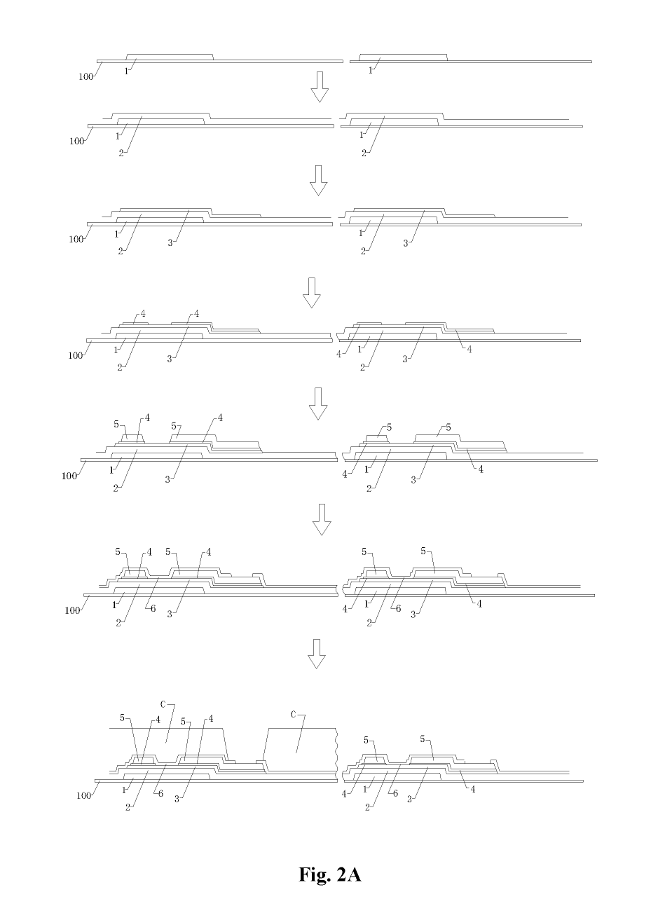

FIG. 1 and FIG. 2 show a method of manufacturing an active switch array substrate provided in the present embodiment, which includes steps described below.

In step 100, a first metal layer is formed on a substrate 100, and the first metal layer is etched to form gate electrodes 1 of active switches.

In step 200, an insulating layer 2 is formed on the substrate 100 and the gate electrodes 1.

In step 300, an active layer 3 and an ohmic contact layer 4 are formed on the insulating layer 2.

In step 400, a second metal layer is formed on the ohmic contact layer 4 and the insulating layer 2; and the second metal layer is etched to form source electrodes and drain electrodes 5 of the active switches.

In step 500, a protective layer 6 is formed on the source electrodes, the drain electrodes 5 and the insulating layer 2.

In step 600, a color filter layer C is formed on the protective layer 6, and the color filter layer is exposed and developed.

In step 700, a photoresist layer W′, which is penetrable by visible light (i.e., transparent or relatively transparent) is formed on the color filter layer C and the protective layer 6.

In step 800, a transparent conducting layer is formed directly on the photoresist layer W′ and the transparent conducting layer is etched to form a pixel electrode layer. An active switch generally refers to a thin-film transistor in the array substrate and is configured to control turning on and off of a pixel unit, and luminous brightness of the pixel unit and the like.

Optionally, in the step 100, the forming a first metal layer on a substrate 100 and etching the first metal layer to form gate electrodes 1 of active switches includes steps described below.

In a step of cleaning, the substrate 100 is cleaned to remove one or more foreign bodies.

In a step of forming a film, a first metal layer is formed on a cleaned surface of the substrate 100 through sputtering deposition.

In a step of coating photoresist, a layer of photoresist is uniformly coated on the formed first metal layer.

In a step of exposure, the photoresist on the substrate 100 is exposed with ultraviolet rays which penetrate a mask and irradiate the photoresist.

In a step of development, an exposed part of the photoresist is dissolved in developing solution, so that remaining photoresist presents a required shape.

In a step of etching, the substrate is immersed into corresponding etching solution or etching gas, and the first metal film uncovered by the photoresist is etched off.

In a step of removing photoresist, residual photoresist is removed and the first metal layer with the required shape is reserved, so as to form scan lines, gate electrodes 1 of the active switches, and common electrodes.

Optionally, in the step 300, part of the active layer 3 is located on the gate electrodes 1; the ohmic contact layer 4 is formed on the active layer 3; and the ohmic contact layer 4 is discontinuous. Optionally, in the step 400, the forming a second metal layer on the ohmic contact layer 4 and the insulating layer, and etching the second metal layer to form source electrodes and drain electrodes 5 of the active switch, includes steps described below.

In a step of forming a film, a second metal layer is formed on the ohmic contact layer 4 and the insulating layer 2 through sputtering deposition.

In a step of coating photoresist, a layer of photoresist is uniformly coated on the formed second metal layer.

In a step of exposure, the photoresist is exposed with ultraviolet rays which penetrate a mask and irradiate the photoresist.

In a step of development, an exposed part of the photoresist is dissolved in developing solution, so that remaining photoresist presents a required shape.

In a step of etching, the substrate is immersed into corresponding etching solution or etching gas, and the second metal film uncovered by the photoresist is etched off.

In a step of removing photoresist, residual photoresist is removed and the second metal layer with the required shape is reserved, so as to form data lines and define source electrodes and drain electrodes 5 of the active switches on the ohmic contact layer.

Optionally, in the step 500, gaps are formed in the protective layer 6 on the drain electrodes 5.

Optionally, in the step 600, the forming a color filter layer on the protective layer 6, and exposing and developing the color filter layer includes steps described below.

A red organic photosensitive layer is coated on the protective layer 6, exposed with a mask, and developed so as to form a red filter layer corresponding to pixels.

A green organic photosensitive layer is coated on the protective layer 6, exposed with a mask, and developed so as to form a green filter layer corresponding to the pixels.

A blue organic photosensitive layer is coated on the protective layer 6, exposed with a mask, and developed so as to form a blue filter layer corresponding to the pixels.

Through the above three steps (in no particular order), the color filter layer C in the present embodiment may be formed.

In the step 700, to ensure a uniform thickness and a smooth surface of the photoresist layer W′, photoresist with a good leveling property may be adopted.

The above color filter layer C in the present embodiment includes a red filter layer, a green filter layer and a blue filter layer, which are horizontally located at a same height. The photoresist layer W′ is made of a relatively transparent photoresist with higher penetration rate. Therefore, the photoresist layer W′ has features of transparent photoresist.

After the step 700, the photoresist layer W′ is exposed by using a mask with through holes and then is developed and etched, so as to remove the insulating layer 2 and the protective layer 6 corresponding to positions of the through holes of the mask to form openings. In this way, the metal layer corresponding to the openings can be exposed outside to form an array.

It can be seen from above embodiment that, in the method of manufacturing an active switch array substrate provided in above embodiment, the photoresist is reserved on the substrate instead of removing the photoresist layer, and a subsequent process of manufacturing pixel electrodes follows. Compared with a technological process of an array having a COA structure and using a WRGB technology in the related art, the present embodiment can omit manufacturing processes of coating, exposing and developing transparent photoresist (white) in the relevant art. This saves device investment expense and subsequent mask expense, and can produce WRGB panels without significantly changing the RGB production lines, thereby shortening production time, reducing production cost and increasing efficiency and productivity of the production lines.

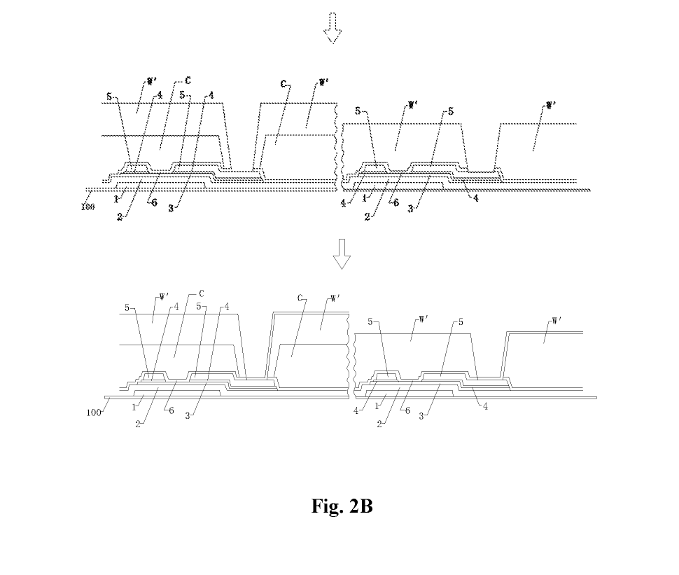

As shown in FIG. 3, the present embodiment further provides an array substrate, which includes a composition structure including:

a substrate 100;

gate electrodes 1 of active switches located on the substrate 100;

an insulating layer 2 located on the substrate 100 and the gate electrodes 1;

an active layer 3 located on the insulating layer 2 and configured to be channels of the active switches;

an ohmic contact layer 4 located on the active layer 3;

source electrodes and drain electrodes 5 of the active switches located on the ohmic contact layer 4 and the insulating layer 2;

a protective layer 6 located on the source electrodes, the drain electrodes 5 and the insulating layer 2;

a color filter layer C, located on the protective layer 6 and including a plurality of light-filtering units;

a photoresist layer W′ located on the color filter layer C and the protective layer 6, and formed by forming photoresist of a high penetration rate for light in a visible spectrum; and

a pixel electrode layer formed directly on the photoresist layer W′.

In the present embodiment, the photoresist in the photoresist layer W′ has a good leveling property.

Optionally, in the array substrate of the present embodiment, a transparent conducting layer is further formed on the photoresist layer W′ and is configured to form pixel electrodes.

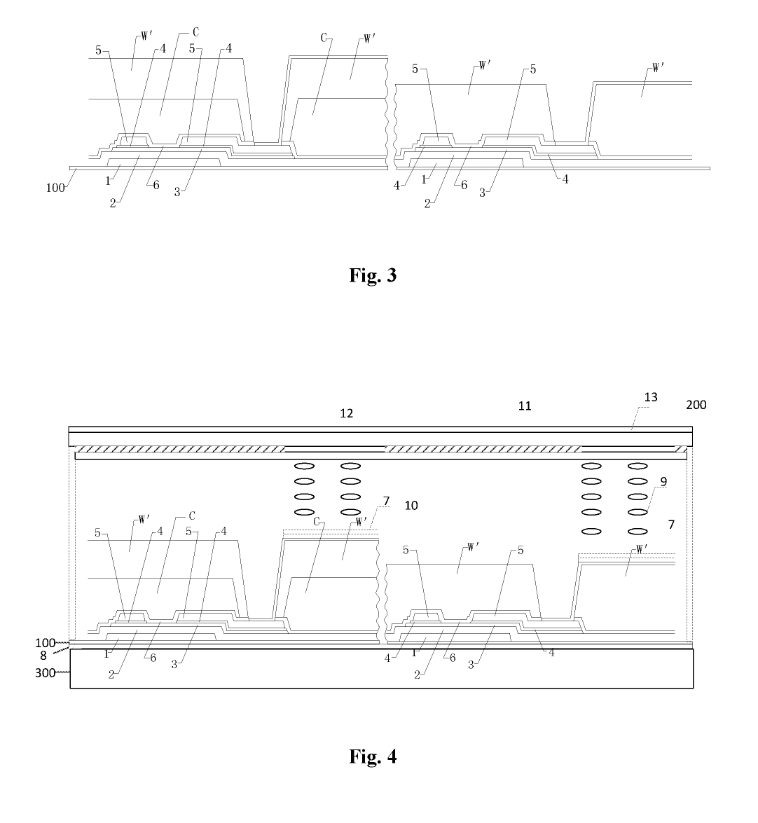

With reference to FIG. 4, the present embodiment further provides a display panel which includes a composition structure including:

a backlight module 300 configured to provide an illumination source;

a first substrate, including: a substrate 100; gate electrodes 1 of active switches located on one side of the substrate 100; an insulating layer 2 located on the substrate 100 and the gate electrodes 1; an active layer 3 located on the insulating layer 2; an ohmic contact layer 4 located on the active layer 3; source electrodes and drain electrodes 5 of the active switches located on the ohmic contact layer 4 and the insulating layer 2; a protective layer 6 located on the source electrodes, the drain electrodes 5 and the insulating layer 2; a color filter layer C located on the protective layer 6; a photoresist layer W′ located on the color filter layer C and the protective layer 6, and formed by forming photoresist of a high penetration rate for light in a visible spectrum; a pixel electrode layer 10 located on the photoresist layer W′; a first alignment film 7 located on the photoresist layer W′; and a first polarizer 8 arranged on the other side of the substrate 100;

a second substrate 200 buckled with the first substrate; and

a liquid crystal layer 9 filling between the first substrate and the second substrate 200.

Optionally, a black matrix layer 11 is arranged on an inner side of the second substrate 200. A second alignment film 12 is arranged on the black matrix layer 11. A second polarizer 13 is arranged on an outer side of the second substrate 200.

Optionally, the substrate 100 is a glass substrate.

Compared with a method of manufacturing a display panel in the related art, in the method of manufacturing a display panel of the present embodiment, the manufacturing processes of coating, exposing and developing transparent photoresist are not needed, and formation of the second insulating layer is also not needed; instead of removing the photoresist layer W′, the photoresist layer W′ is reserved on the panel and a subsequent process of manufacturing pixel electrodes follows. Although a thickness above the color filter layer C is increased since the photoresist layer W′ is not removed from the display panel of the present embodiment, the photoresist layer W′ can reduce loads of signal lines.

It can be seen that the display panel of the present embodiment can save device investment expense for producing the transparent photoresist and subsequent mask expense, and can produce panels with the white, red, green and blue technology under a condition of slightly changing the red, green and blue production lines, thereby shortening production time, reducing production cost and increasing efficiency and productivity of the production lines.

What is claimed is:

1. A method of manufacturing an array substrate, comprising:
forming a plurality of gate electrodes of a plurality of active switches, an insulating layer, an active layer and an ohmic contact layer on a substrate;
forming a plurality of source electrodes and a plurality of drain electrodes of the active switches on the ohmic contact layer and the insulating layer;
forming a protective layer on the source electrodes, the drain electrodes and the insulating layer;
forming a color filter layer on the protective layer, and exposing and developing the color filter layer;
forming a photoresist layer, which is penetrable by visible light, on the color filter layer and the protective layer; and
forming a transparent conducting layer directly on the photoresist layer, and etching the transparent conducting layer to form a pixel electrode layer.

2. The method of manufacturing according to claim 1, wherein the forming a plurality of gate electrodes of a plurality of active switches on a substrate comprises:
cleaning the substrate to remove one or more foreign bodies;
forming a metal film through sputtering deposition on a cleaned surface of the substrate;
coating a layer of photoresist uniformly on the formed metal film;
exposing the photoresist with ultraviolet rays which penetrate a mask and irradiate the photoresist;
dissolving an exposed part of the photoresist in developing solution, so that remaining photoresist presents a required shape;
immersing the substrate into corresponding etching solution or etching gas and etching off the metal film uncovered by the photoresist; and
removing residual photoresist and reserving the metal film with the required shape to form a plurality of scan lines, a plurality of gate electrodes of the active switches, and a plurality of common electrodes.

3. The method of manufacturing according to claim 1, wherein the forming a plurality of source electrodes and a plurality of drain electrodes of the active switches on the ohmic contact layer and the insulating layer comprises:
forming a metal film on the ohmic contact layer and the insulating layer through sputtering deposition;
coating a layer of photoresist uniformly on the formed metal film;
exposing the photoresist with ultraviolet rays which penetrate a mask and irradiate the photoresist;
dissolving an exposed part of the photoresist in developing solution so that remaining photoresist presents a required shape;
immersing the substrate into corresponding etching solution or etching gas and etching off the metal film uncovered by the photoresist; and
removing residual photoresist and reserving the metal film with the required shape to form a plurality of data lines and define a plurality of source electrodes and a plurality of drain electrodes of the active switches on the ohmic contact layer.

4. The method of manufacturing according to claim 1, wherein the forming a color filter layer on the protective layer, and exposing and developing the color filter layer comprises:
coating a first organic photosensitive layer on the insulating layer, exposing the first organic photosensitive layer with a mask, and developing the first organic photoresist layer to form a first filter layer corresponding to pixels;
coating a second organic photosensitive layer on the insulating layer, exposing the second organic photosensitive layer with a mask, and developing the second organic photoresist layer to form a second filter layer corresponding to the pixels; and
coating a third organic photosensitive layer on the insulating layer, exposing the third organic photosensitive layer with a mask, and developing the third organic photosensitive layer to form a third filter layer corresponding to the pixels.

5. The method of manufacturing according to claim 4, wherein the first organic photosensitive layer is a red organic photosensitive layer, and the first filter layer is a red filter layer;
the second organic photosensitive layer is a green organic photosensitive layer, and the second filter layer is a green filter layer; and
the third organic photosensitive layer is a blue organic photosensitive layer, and the third filter layer is a blue filter layer.

6. The method of manufacturing according to claim 5, wherein the red filter layer, the green filter layer and the blue filter layer are located at a same height.

7. The method of manufacturing according to claim 1, wherein the formed photoresist layer has a leveling property.

8. The method of manufacturing according to claim 1, wherein the forming a plurality of gate electrodes of a plurality of active switches, an insulating layer, an active layer and an ohmic contact layer on a substrate comprises:
forming the gate electrodes of the active switches and an insulating layer on the substrate;
forming the active layer on the insulating layer, wherein part of the active layer covers the gate electrodes; and
forming ohmic contact layers on both ends of the active layer of each active switch, wherein the ohmic contact layers on both ends of the active layer are separated.

9. The method of manufacturing according to claim 1, wherein the photoresist layer comprises transparent photoresist.

10. (canceled)

11. An array substrate, comprising:
a substrate;
a plurality of gate electrodes of a plurality of active switches, which are located on the substrate;
an insulating layer, which is located on the substrate and the gate electrodes;
an active layer, which is located on the insulating layer and configured to be a plurality of channels of the active switches;
an ohmic contact layer, which is located on the active layer;
a plurality of source electrodes and a plurality of drain electrodes of the active switches, which are located on the ohmic contact layer and the insulating layer;
a protective layer, which is located on the source electrodes, the drain electrodes and the insulating layer;
a color filter layer, which is located on the protective layer and comprises a plurality of filter units;
a photoresist layer, which is located on the color filter layer and the protective layer and is formed by forming photoresist which is penetrable by visible light; and
a pixel electrode layer, which is directly formed on the photoresist layer.

12. The array substrate according to claim 11, wherein the color filter layer comprises a red filter layer, a green filter layer and a blue filter layer.

13. The array substrate according to claim 12, wherein the red filter layer, the green filter layer and the blue filter layer are located at a same height.

14. A display panel, comprising:
a backlight module, which is configured to provide an illumination source;
a first substrate, which comprises:
a substrate;
a plurality of gate electrodes of a plurality of active switches, which are located on one side of the substrate;
an insulating layer, which is located on the substrate and the gate electrodes;
an active layer, which is located on the insulating layer;
an ohmic contact layer, which is located on the active layer;
a plurality of source electrodes and a plurality of drain electrodes of the active switches, which are located on the ohmic contact layer and the insulating layer;
a protective layer located on the source electrodes, the drain electrodes and the insulating layer;
a color filter layer, which is located on the protective layer;
a photoresist layer, which is located on the color filter layer and the protective layer and is formed by forming photoresist which is penetrable by visible light;
a pixel electrode layer, which is directly located on the photoresist layer;
a first alignment film, which is located on the photoresist layer; and
a first polarizer, which is arranged on the other side of the first glass substrate;
a second substrate, which is buckled with the first substrate; and
a liquid crystal layer, which fills between the first substrate and the second substrate.

15. The display panel according to claim 14, wherein a black matrix layer is arranged on an inner side of the second substrate; a second alignment film is arranged on the black matrix layer; and a second polarizer is arranged on an outer side of the second substrate.

16. The display panel according to claim 14, wherein the substrate is a glass substrate.

17. The display panel according to claim 14, wherein the color filter layer comprises a red filter layer, a green filter layer and a blue filter layer.

18. The display panel according to claim 17, wherein the red filter layer, the green filter layer and the blue filter layer are located at a same height.

19. The display panel according to claim 14, wherein the pixel electrode layer is made of indium tin oxide.

20. The display panel according to claim 14, wherein the insulating layer is made of silicon oxide.
